(19) United States
(12) Patent Application Publication
(10) Pub. No.: US 2007/0066056 A1
(43) Pub. Date: Mar. 22, 2007

(54) Method of removing a photoresist and method of manufacturing a semiconductor device using the same

(75) Inventors: Jong-Kyu Kim, Seocho-gu (KR); Sung-Gil Choi, Yongin-si (KR); Jang-Bin Yim, Yongin-si (KR); Sang-Dong Kwon, Suwon-si (KR); Ki-Jeong Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/447,032

(22) Filed: Jun. 6, 2006

(30) Foreign Application Priority Data
Jun. 10, 2005 (KR) 2005-0049679

(51) Int. Cl. H01L 21/44; H01L 21/4763

(52) U.S. Cl. 438/671; 438/636

(57) ABSTRACT

Example embodiments of the present invention provide a method of removing a photoresist and a method of manufacturing a semiconductor device using the same. In a method of removing a photoresist and a method of manufacturing a semiconductor device, a plasma including active ions and radicals may be generated. The active ions may be modified into directional active ions. The photoresist may be etched using the directional active ions as main etching factors and/or the radicals as subsidiary etching factors. The photoresist may be completely removed from the semiconductor device such as a lower electrode. Thus, the likelihood of an increase in electrical resistance due to residual photoresist may decrease.

### PRIORITY STATEMENT

This application claims priority under 35 USC §119 to Korean Patent Application No. 2005-49679 filed on Jun. 10, 2005, in the Korean Intellectual Property Office, the contents of which are herein incorporated by references in their entirety.

### BACKGROUND OF THE INVENTION

1. Field of the Invention

Example embodiments of the present invention relate to a method of removing a photoresist and a method of manufacturing a semiconductor device using the same. More particularly, example embodiments of the present invention relate to a method of removing a photoresist using active ions and a method of manufacturing a semiconductor device using the same.

2. Description of the Related Art

Recently, a reduction in a wiring width in a semiconductor device may trigger a reduction in a unit cell area of the semiconductor device. For example, as a width of a wiring in a semiconductor device (e.g., a dynamic random access memory (DRAM) device) is reduced less than about 0.1 μm, a unit cell area of the semiconductor device may also be reduced. Thus, a lower electrode of a capacitor may be formed in a stacked shape or a cylindrical shape to ensure a required capacitance of the capacitor in the semiconductor device. In a DRAM device having a wiring width of less than about 0.1 μm, an aspect ratio of the capacitor may increase in order to obtain the capacitance within the narrower unit cell area. The aspect ratio is the ratio of the height to the inner diameter.

A capacitor generally includes a lower electrode, a dielectric layer and/or an upper electrode. In order to form the lower electrode, after a conductive layer is formed on a mold layer pattern having an opening, the conductive layer may be partially removed by a chemical mechanical polishing (CMP) process, an etch back process or a combination thereof. The partially removed conductive layer may form a conductive layer pattern in the opening. When the molded layer pattern is removed using a cleaning solution including hydrogen fluoride, the lower electrode is formed.

In the formation of the lower electrode, the cleaning solution may etch the lower electrode and cause damage to the lower electrode and/or a contact pad beneath the lower electrode. To solve this problem, a photoresist film may be formed, as a sacrificial layer, to fill the opening before forming the conductive layer pattern. The photoresist film may prevent the cleaning solution from etching the lower electrode when removing the mold layer pattern using the cleaning solution.

The photoresist film may not be completely removed from the lower electrode when the lower electrode has a cylindrical shape with a high aspect ratio. The photoresist film may not be completely removed by an ashing process using an oxygen plasma. When the residual photoresist film exists on the cylindrical lower electrode, a failure of the semiconductor device including the lower electrode may occur.

To remove the photoresist film from the lower electrode, an oxygen plasma ashing process may be performed at a temperature of about 150° C. to about 250° C. When the ashing process is performed at the temperature of about 150° C. to about 250° C., the lower electrode may deteriorate and/or be oxidized, reducing the capacitance of the capacitor. When the oxygen plasma ashing process is performed at a temperature higher than about 250° C. for a longer time to more efficiently remove the photoresist film from the lower electrode, the lower electrode may deteriorate even more.

The conventional art acknowledges various methods of removing a photoresist in a manufacturing process for a capacitor.

According to the conventional art, a photoresist may be removed at a temperature of about 20° C. to about 40° C. through an ashing process using a gas including oxygen (O₂) and trifluoromethane (CHF₃) under a gas pressure of about 100 Pa with a power of about 1,000 W.

The conventional art also acknowledges that a photoresist may be removed at a temperature of about 200° C. to about 250° C. through an ashing process using a gas including a water (H₂O) vapor, nitrogen (N₂) and tetrafluorocarbon (CF₄) under a gas pressure of about 1 Torr to about 3 Torr with a power of about 800 W to about 1,500 W.

Another method acknowledged by the conventional art includes removing the photoresist at a temperature of about 20° C. to about 50° C. through an ashing process using a plasma including a water (H₂O) vapor and tetrafluorocarbon (CF₄) under a gas pressure of about 200 mTorr to about 500 mTorr.

### SUMMARY OF THE INVENTION

Example embodiments of the present invention relate to a method of removing a photoresist and a method of manufacturing a semiconductor device using the same.

Other example embodiments of the present invention provide a method of removing a photoresist using active ions and a method of manufacturing a semiconductor device using the same.

According to an example embodiment of the present invention, there is provided a method of removing a photoresist. In the method of removing the photoresist, a plasma including active ions and radicals may be generated. The active ions may be modified into directional active ions. The photoresist may be etched using the directional active ions as main etching factors and the radicals as subsidiary etching factors.

In an example embodiment of the present invention, the plasma may include about 10 mole percent to about 90 mole percent of the active ions.

In other example embodiments of the present invention, the active ions may be modified into the directional active ions by applying a bias voltage. The bias voltage may be in a range of about 100V to about 300V.

Etching the photoresist may be performed at a temperature about 10° C. to about 50° C. In an example embodiment of the present invention, etching the photoresist may be performed under a pressure of about 10 mTorr to about 800 mTorr.

After removing the photoresist, residual photoresist may be removed. The photoresist may fill an opening of a desired structure. An aspect ratio of the opening may be about 1:9 to about 1:40.

According to example embodiments of the present invention, there is provided a method of manufacturing a semiconductor device. In the method, a mold layer having a plurality of openings may be formed on a substrate. A conductive layer may be formed on a sidewall, a bottom face of the opening and/or the mold layer. A photoresist film may be formed on the conductive layer to fill the opening. The photoresist film and/or the conductive layer may be partially removed to form a photoresist pattern. A plasma including active ions and radicals may be generated. The active ions may be modified into directional active ions. The photoresist pattern may be etched using the directional active ions as main etching factors or the radicals as subsidiary etching factors. Modifying the active ions into the directional active ions may be performed by applying a bias voltage.

In an example embodiment of the present invention, etching the photoresist pattern may be performed at a temperature of about 10° C. to about 50° C. Etching the photoresist pattern may be performed under a pressure of about 10 mTorr to about 800 mTorr.

In an example embodiment of the present invention, after removing the photoresist pattern, residual photoresist from the photoresist pattern may be removed. The photoresist may fill an opening of a desired structure. An aspect ratio of the opening may be about 1:9 to about 1:40.

According to example embodiments of the present invention, a photoresist may be completely removed such that the photoresist may not remain in a semiconductor device, for example, on a lower electrode. The photoresist may be removed using radicals and ions that randomly move such that the photoresist, in the opening, having a higher aspect ratio may be removed. The likelihood of an increase in electrical resistance, due to the residual photoresist remaining on the semiconductor device, may decrease. In addition, the photoresist may be removed without increasing the removal process time. Thus, a manufacturing process of a semiconductor device may have increased throughput.

### BRIEF DESCRIPTION OF THE DRAWINGS

Example embodiments of the present invention will become readily apparent by reference to the following detailed description when considering in conjunction with the accompanying drawings. FIGS. 1 to 11 represent non-limiting example embodiments of the present invention as described herein.

FIGS. 1 to 3 are cross-sectional views illustrating a method of removing a photoresist in accordance with an example embodiment of the present invention; and

FIGS. 4 to 11 are cross-sectional views illustrating a method of manufacturing a semiconductor device in accordance with an example embodiment of the present invention.

### DETAILED DESCRIPTION OF EXAMPLE EMBODIMENTS OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the present invention are capable of various modifications and alternative forms, embodiments thereof are shown by way of example in the drawings and will herein be described in detail. It should be understood, however, that there is no intent to limit example embodiments of the present invention to the particular forms disclosed, but on the contrary, example embodiments of the present invention are to cover all modifications, equivalents, and alternatives falling within the scope of the present invention. Like numbers refer to like elements throughout the description of the figures.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

FIGS. 1 to 3 are cross sectional views illustrating a method of removing a photoresist in accordance with an example embodiment of the present invention.

Referring to FIG. 1, a substrate 11 including a photoresist pattern 12 thereon may be loaded into a chamber 10. The substrate 11 having the photoresist pattern 12 may be loaded into the chamber 10 that may remove the photoresist pattern 12 by using active ions and radicals.

In an example embodiment of the present invention, the photoresist pattern 12 may serve as an etching mask for forming a desired pattern on the substrate 11.

When the photoresist pattern 12 is used as the etching mask, a surface treatment process may be performed on the substrate 11 in order to remove contaminants from the substrate 11. A photoresist film may be formed on the substrate 11 by coating with a photoresist composition. A first baking process may be performed on the substrate 11 having the photoresist film thereon. The photoresist film may be selectively exposed to a light using an exposure apparatus. A second baking process, a developing process, a third baking process and/or a rinsing process may be executed on the substrate 11 to form the photoresist pattern 12 on the substrate 11.

In another example embodiment of the present invention, the photoresist pattern 12 may function as an etching mask for forming an opening through a conductive layer. The photoresist pattern 12 may function as an insulation layer positioned on the substrate 11.

In another example embodiment of the present invention, the photoresist pattern 12 may function as a sacrificial layer for forming a lower electrode of a capacitor in a semiconductor device.

The photoresist pattern 12 may be used as the sacrificial layer for forming the lower electrode of the capacitor by using the photoresist pattern 12 to fill an opening of the lower electrode having a cylindrical shape. The opening of the lower electrode may generally have an aspect ratio (ratio of height to inner diameter) of about 1:9 to about 1:40. For example, the opening of the lower electrode may have an aspect ratio of about 1:15 to about 1:30. The photoresist pattern 12 filling the opening is completely removed after the formation of the lower electrode. However, due to the opening of the lower electrode having the aspect ratio of about 1:15 to about 1:30, the photoresist pattern 12 may not be completely removed from the opening of the lower electrode through a conventional ashing process using an oxygen plasma or an ozone plasma

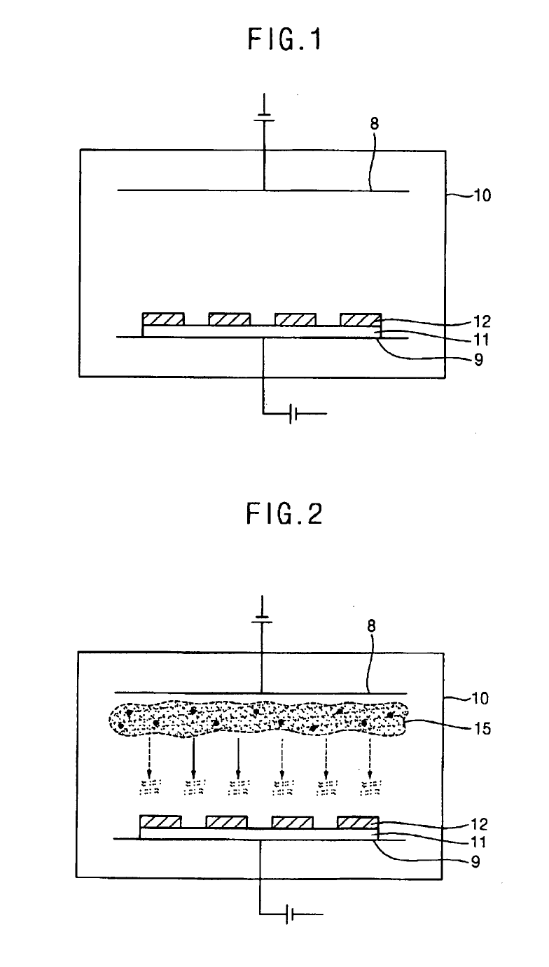

Referring to FIG. 2, after the substrate 11 is loaded into the chamber 10, a plasma 15 including active ions and radicals may be generated in the chamber 10. The active ions in the plasma 15 may be modified into directional active ions.

The active ions in the plasma 15 may be generated in the chamber 10 when a higher voltage is applied to a processing gas introduced into the chamber 10. When a bias voltage is applied to a substrate stage 9 of the chamber 10, the active ions may be modified into the directional active ions, inducing the directional active ions toward the substrate 11. When the bias voltage is not applied to the stage 9, the directional active ions may not be generated in the chamber 10.

In an example embodiment of the present invention, the plasma 15 may be generated in the chamber 10 by a capacitively coupled plasma generating process. In another example embodiment of the present invention, the plasma 15 may be generated over the substrate 11 by an inductive coupled plasma generating process.

When the plasma 15 is generated by the inductive coupled plasma generating process, a relatively lower operating power may be required. Structural conditions required in an apparatus may not be strict. In addition, the plasma 15 having a higher density may be generated through the inductive coupled plasma generating process.

An apparatus for performing the inductive coupled plasma generating process may include the chamber 10 and a gas supply unit (not shown) for providing the processing gas into the chamber 10. The substrate 11 may be introduced into the chamber 10, and then a process for removing the photoresist pattern 12 from the substrate 11 may be performed in the chamber 10. The processing gas may include an oxygen (O₂) gas, a nitrogen (N₂) gas, an argon (Ar) gas, a hydrogen (H₂) gas, etc.

The apparatus may further include a gas inlet and a gas outlet. The processing gas may be introduced into the chamber 10 through the gas inlet. Particles and/or impurities generated during the process for removing the photoresist pattern 12 and/or un-reacted gas may be discharged from the chamber 10 through the gas outlet. In addition, an internal pressure of the chamber 10 may be controlled by the gas outlet.

The apparatus may include the substrate stage 9 where the substrate 11 may be placed and the bias voltage may be applied. The bias voltage may be applied to the substrate 11 through the substrate stage 9 such that the directional active ions are generated in the plasma 15. The directional active ions may be induced toward the substrate 11. In an example embodiment of the present invention, the bias voltage may be in a range of about 100V to 300V.

The apparatus may further include a plasma generator 8. When a radio frequency (RF) power is applied to the plasma generator 8, the plasma generator 8 may generate the plasma 15 from the processing gas in the chamber 10.

The plasma 15 generated in the chamber 10 may include directional active ions and radicals. In an example embodiment of the present invention, the plasma 15 may include about 10 mole percent to about 90 mole percent of the directional active ions. In another example embodiment of the present invention, the plasma 15 may include about 30 mole percent to about 70 mole percent of the directional active ions.

The directional active ions may function as main etching factors to remove the photoresist pattern 12 from the substrate 11. The radicals may function as subsidiary etching factors to remove the photoresist pattern 12 from the substrate 11. The radicals may be electrically neutral. When the bias voltage is applied to the substrate stage 9, the radicals may or may not be directional relative to the substrate 11. When residual photoresist remains in an opening having a high aspect ratio, the radicals alone may not completely remove the residual photoresist from the opening.

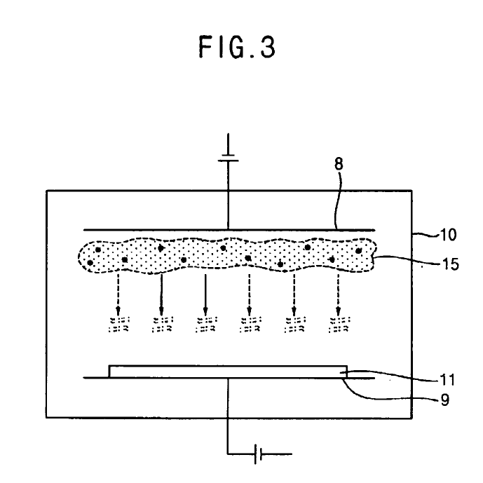

Referring to FIG. 3, the photoresist pattern 12 formed on the substrate 11 may be substantially removed by the directional active ions. In an example embodiment of the present invention, the photoresist pattern 12 may be removed at a temperature of about 10° C. to about 50° C. and/or under a pressure of about 10 mTorr to about 800 mTorr. In another example embodiment of the present invention, the photoresist pattern 12 may be removed at a temperature of about 10° C. to about 40° C. and/or under a pressure of about 10 mTorr to about 500 mTorr.

The photoresist pattern 12 may be removed by a reaction between polymers in the photoresist pattern 12 and the directional active ions. The photoresist pattern 12 may be removed at a temperature of below about 250° C. and under a pressure of below about 1 Torr. When the photoresist pattern 12 is removed from the substrate 11 by the directional active ions, the occurrence of undesirable processes (e.g., oxidation of a conductive layer or deterioration of adhesion characteristics between a metal layer and an insulation layer) may be decreased.

A rinsing process may be performed on the substrate 11. The rinsing process may remove residual photoresist, from the photoresist pattern 12, remaining on the substrate 11. In an example embodiment of the present invention, the rinsing process may include an ultrasonic cleaning process in which an ultrasonic wave may be applied to the substrate 11 immersed into a bath having a cleaning solution. In another example embodiment of the present invention, the rinsing process may include a spraying process in which deionized water is sprayed onto the substrate 11 while the substrate 11 is revolved. The deionized water may more easily remove the residual photoresist, from the photoresist pattern 12, decomposed by the directional active ions.

In an example embodiment of the present invention, a photoresist pattern may be completely removed from a substrate without damage to the substrate or deterioration of structures positioned on the substrate. Thus, a semiconductor device may have increased reliability. Further, a manufacturing process of the semiconductor device may have an enhanced throughput.

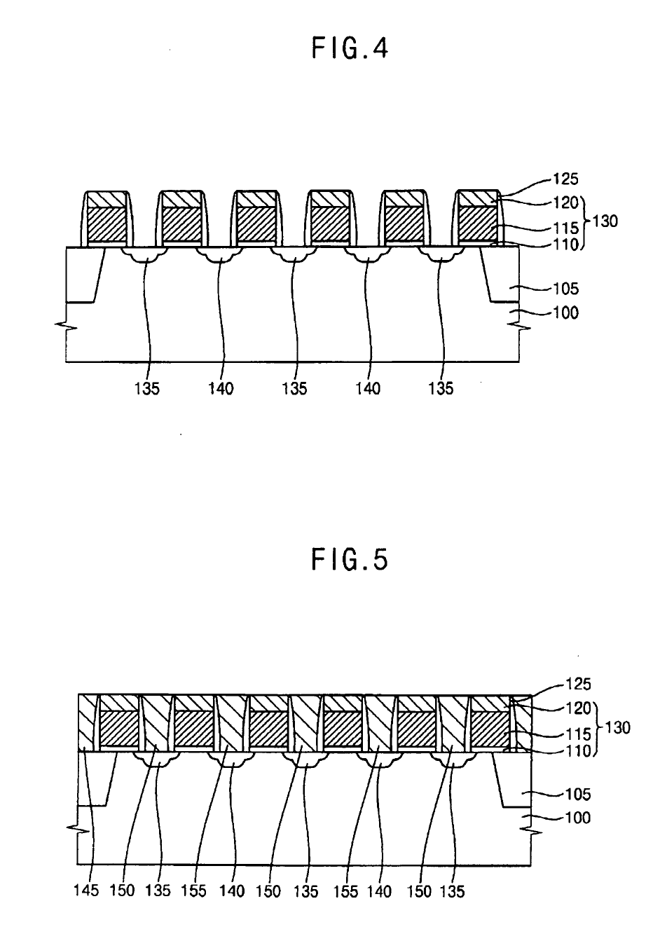

FIGS. 4 to 11 are cross-sectional views illustrating a method of manufacturing a semiconductor device in accordance with an example embodiment of the present invention.

FIG. 4 is a cross-sectional view illustrating example processes of forming gate structures 130 on a substrate 100. FIG. 4 also illustrates example processes of forming first and second contact regions 135 and 140 in the substrate 100.

Referring to FIG. 4, an isolation layer 105 may be formed on the substrate 100 by a shallow trench isolation (STI) process to define an active region and/or a field region on the substrate 100. The substrate 100 may include a silicon wafer or a silicon-on-insulator (SOI) substrate. The isolation layer 105 may be formed by a thermal oxidation process, a chemical vapor deposition (CVD) process or any other appreciated method.

A gate insulation layer, a first conductive layer and/or a gate mask 120 are successively formed on the substrate 100. The gate insulation layer may be patterned to form a gate insulation layer pattern 110 on the substrate 100. The first conductive layer may be patterned to form a gate electrode 115 on the gate insulation layer pattern 110. In an example embodiment of the present invention, the first conductive layer may be formed using polysilicon doped with impurities. In another example embodiment of the present invention, the first conductive layer may have a polycide structure that may include a polysilicon film and/or a metal silicide film formed on the polysilicon film. The gate mask 120 may be formed using a material having an etching selectivity relative to that of a first insulating interlayer 145 (see FIG. 5) formed in a subsequent process.

The first conductive layer and the gate insulation layer may be successively patterned using the gate mask 120 as an etching mask. A gate structure 130 including a gate insulation layer pattern 110, a gate electrode 115 and/or the gate mask 120 may be formed on the substrate 100. A gate spacer 125 may be formed on a sidewall of the gate structure 130. Word lines disposed parallel with each other may be formed on the substrate 100.

Impurities may be implanted through surface portions of the substrate 100 exposed between the gate structures 130 by an ion implantation process (IIP) using the gate structure 130 as an ion implantation mask. A thermal treatment process may be performed on the substrate 100. A first contact region 135 and/or a second contact region 140 may be formed on the substrate 100. In an example embodiment of the present invention, the first contact region 135 may be a capacitor contact region and the second contact region 140 may be a bit line contact region.

FIG. 5 is a cross-sectional view illustrating example processes of forming first pads 150, second pads 155 and the first insulating interlayer 145 on the substrate 100.

Referring to FIG. 5, a first insulating interlayer 145 may be formed on the substrate 100 to cover the gate structures 130. The first insulating interlayer 145 may be formed using an oxide (e.g., boro phosphor silicate glass (BPSG), phosphor silicate glass (PSG), undoped silicate glass (USG), spin on glass (SOG), plasma enhanced-tetraethyl orthosilicate (PE-TEOS), high density plasma-chemical vapor deposition (HDP-CVD) oxide, etc.). These oxides may be used alone or in a mixture thereof.

The first insulating interlayer 145 may be partially removed by a chemical mechanical polishing (CMP) process, an etch back process or a combination thereof until the gate structure 130 is exposed. Thus, an upper portion of the first insulating interlayer 145 may be planarized.

A first photoresist pattern (not shown) may be formed on the first insulating interlayer 145. Portions of the first insulating interlayer 145 exposed by the photoresist pattern may be etched anisotropically to form first contact holes through the first insulating interlayer 145. The first contact holes may expose the first contact regions 135 and second contact regions 140 in the substrate 100.

In an example embodiment of the present invention, the first contact holes may be formed through a self-alignment process. A portion of the first contact holes may expose the first contact region 135 that corresponds to the capacitor contact region. Another portion of the first contact holes may expose the second contact region 140 that corresponds to the bit line contact region.

The first photoresist pattern may be removed. In an example embodiment of the present invention, the first photoresist pattern may be removed using a plasma including directional active ions. The plasma etching process may be substantially similar to the method described with reference to FIGS. 1 to 3.

In another example embodiment of the present invention, the first photoresist pattern may be removed by an ashing process using oxygen and/or a stripping process.

A second conductive layer may be formed on the first insulating interlayer 145 to fill the first contact holes. The second conductive layer may be formed using polysilicon heavily doped with impurities or a metal (e.g., tungsten (W), titanium (Ti), tantalum (Ta), aluminum (Al), copper (Cu), etc.). The second conductive layer may be partially removed by a CMP process, an etch back process or a combination thereof until the first insulating interlayer 145 is exposed.

A first pad 150 and/or a second pad 155 may be formed in the first contact holes by a self-alignment process. For example, the first pad 150 may be formed on the first contact region 135. In addition, the second pad 155 may be formed on the second contact region 140.

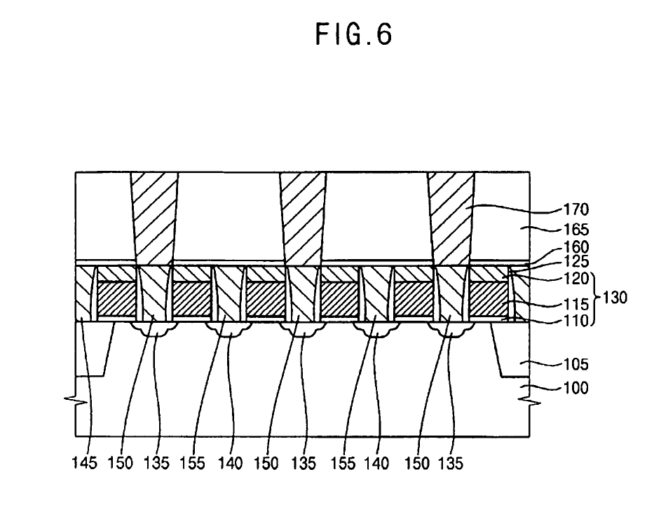

FIG. 6 is cross-sectional view illustrating example processes of forming second insulating interlayers 160, third insulating interlayers 165, a third pad (not shown) and a fourth pad 170.

Referring to FIG. 6, a second insulating interlayer 160 may be formed on the first pads 150, second pads 155 and/or the first insulating interlayer 145. The second insulating interlayer 160 may electrically insulate the first pad 150 with a bit line (not shown). The second insulating interlayer 160 may be formed using an oxide (e.g., BPSG, PSG, USG, SOG, PE-TEOS, HDP-CVD oxide, etc.).

A second photoresist pattern (not shown) may be formed on the second insulating interlayer 160. The second insulating interlayer 160 may be etched using the second photoresist pattern as an etching mask to form a second contact hole through the second insulating interlayer 160. The second contact hole may expose the second pad 155.

The second photoresist pattern may be removed. In an example embodiment of the present invention, the second photoresist pattern may be removed using a plasma including directional active ions. The plasma etching process may be substantially similar to the method described with reference to FIGS. 1 to 3. In another example embodiment of the present invention, the second photoresist pattern may be removed by an ashing process using oxygen and/or a stripping process.

A third conductive layer may be formed on the second insulating interlayer 160 to fill the second contact hole. A bit line mask may be formed on the third conductive layer. The third conductive layer may be patterned using the bit line mask to form a third pad in the second contact hole. A bit line including a bit line electrode and the bit line mask may be simultaneously formed on the second insulating interlayer 160. The third pad may electrically connect the bit line with the second pad 155.

A nitride layer may be formed on the second insulating interlayer 160 and the bit line. The nitride layer may be etched anisotropically to form a bit line spacer on each sidewall of the bit line. The bit line spacer may protect the bit line during a formation of a fourth pad 170.

A third insulating interlayer 165 may be formed on the second insulating interlayer 160 to cover the bit line including the bit line spacer. The third insulating interlayer 165 may be formed using an oxide (e.g., BPSG, PSG, USG, SOG, PE-TEOS, HDP-CVD oxide, etc.).

The third insulating interlayer 165 may be partially removed by a CMP process, an etch back process or a combination thereof until the bit line is exposed. A third photoresist pattern may be formed on the third insulating interlayer 165. The third insulating interlayer 165 and the second insulating interlayer 160 may be etched anisotropically using the third photoresist pattern as an etching mask. Thus, a third contact hole exposing the first pad 150 may be formed. The third contact hole may be formed to be self-aligned to the bit line.

The third photoresist pattern may be removed. In an example embodiment of the present invention, the third photoresist pattern may be removed using a plasma including directional active ions. The process for removing the third photoresist pattern may be substantially similar to the method described with reference to FIGS. 1 to 3.

In another example embodiment of the present invention, the third photoresist pattern may be removed by an ashing process using oxygen and/or a stripping process.

A fourth conductive layer may be formed on the third insulation layer 165 to fill the third contact hole. The fourth conductive layer may be partially removed by a CMP process, an etch back process or a combination thereof until the third insulating interlayer 165 and the bit line are exposed. Thus, the fourth pad 170 may be formed in the third contact hole. The fourth pad 170 may be formed using polysilicon doped with impurities or a metal (e.g., tungsten (W), titanium (Ti), tantalum (Ta), aluminum (Al), copper (Cu), etc.). The fourth pad 170 may have contact with the first pad 150 formed on the second contact region 135. In addition, the fourth pad 170 may electrically connect the first pad 150 with a lower electrode formed on a subsequent process.

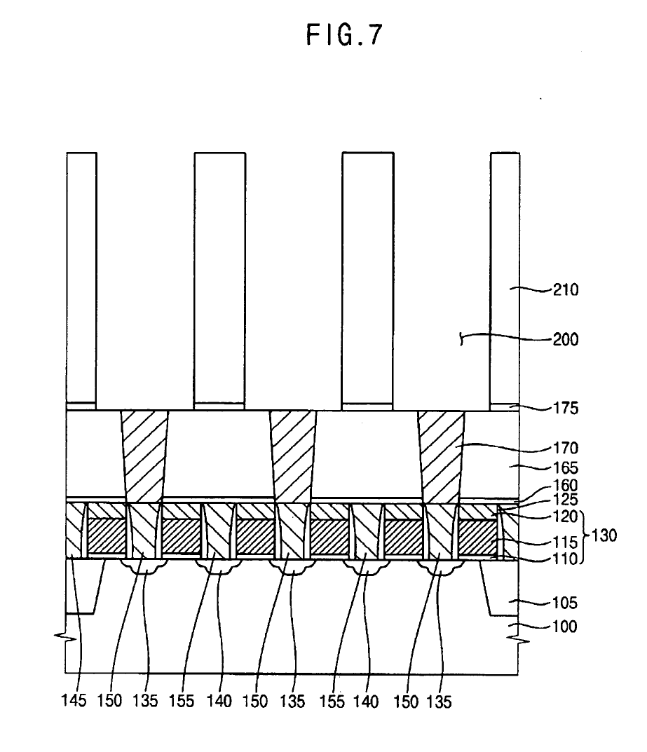

FIG. 7 is a cross-sectional view illustrating example processes of forming an etch stop layer 175 and a mold layer 210 including an opening 200.

Referring to FIG. 7, an etch stop layer 175 may be formed on the fourth pad 170, the third insulating interlayer 165 and/or the bit line. The etch stop layer 175 may protect the fourth pad 170 in subsequent etching processes. In an example embodiment of the present invention, the etch stop layer 175 may be formed to have a thickness of about 10 Å to about 300 Å. In addition, the etch stop layer 175 may be formed using a nitride or a metal oxide.

A mold layer 210 may be formed on the etch stop layer 175. The mold layer 210 may be formed using an oxide (e.g., BPSG, PSG, USG, SOG, PE-TEOS, HDP-CVD oxide, etc.). The mold layer 210 may have a thickness of about 10,000 Å A to about 20,000 Å. The thickness of the mold layer 210 may vary according to a required capacitance of a capacitor.

A mask pattern (not shown) may be formed on the mold layer 210. The mask pattern may be formed using a material having an etching selectivity relative to an etching selectivity of the mold layer 210. For example, when the mold layer 210 is formed using an oxide (e.g., silicon oxide), the mask pattern may be formed using a nitride (e.g., silicon nitride).

The mold layer 210 and/or the etch stop layer 175 may be selectively etched using the mask pattern as an etching mask to form an opening 200 exposing the fourth pad 170. In an example embodiment of the present invention, the opening 200 may have an aspect ratio of about 1:9 to about 1:40. In another example embodiment of the present invention, the opening may be formed to have an aspect ratio of about 1:15 to about 1:30.

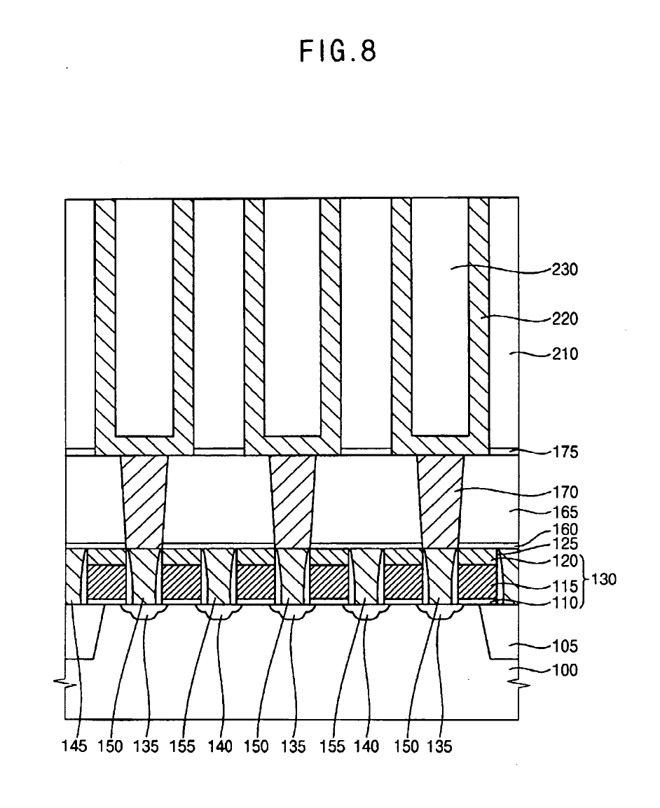

FIG. 8 is a cross-sectional view illustrating example processes of forming a lower electrode layer and a sacrificial photoresist film.

Referring to FIG. 8, a lower electrode layer may be conformably formed on an inner wall of the opening 200 and/or the mask pattern. In an example embodiment of the present invention, the lower electrode layer may be formed using a metal nitride (e.g., titanium nitride). In another example embodiment of the present invention, the lower electrode layer may be formed using polysilicon doped with impurities. In addition, the lower electrode layer may have a thickness of about 300 Å to about 500 Å.

A sacrificial photoresist film may be formed on the lower electrode layer to fill the opening 200. In particular, a photoresist composition may be coated on the lower electrode layer. A first baking process may be performed on the substrate 100 to form a preliminary photoresist film having increased adhesive characteristics relative to the lower electrode layer. An exposure process may be performed on the preliminary photoresist film. Then, a second baking process may be carried out to form the sacrificial photoresist film.

The lower electrode layer and/or the sacrificial photoresist film may be partially removed by a CMP process, an etch back process or a combination thereof until the mold layer 210 is exposed. Thus, a lower electrode 220 having a cylindrical shape may be formed in the opening 200. Simultaneously, a sacrificial photoresist pattern 230 may be formed on the lower electrode 220 to fill the opening 200.

The sacrificial photoresist pattern 230 may decrease the possibility of damaging the lower electrode 220 in an etching process for removing the mold layer 210. When the sacrificial photoresist pattern 230 fills the opening 220, the sacrificial photoresist pattern 230 may not be completely removed by a conventional ashing process using an oxygen plasma or an ozone plasma

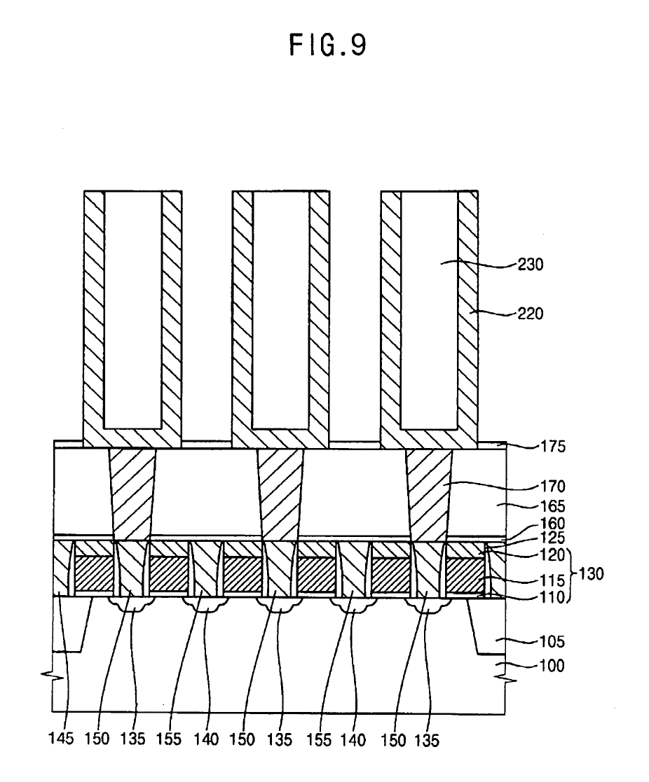

FIG. 9 is a cross sectional view illustrating an example process of removing the mold layer 210.

Referring to FIG. 9, the mold layer 210 may be completely removed to expose an outer wall of the lower electrode 220. When the sacrificial photoresist pattern 230 has an etching selectivity relative to the mold layer 210, the sacrificial photoresist pattern 230 may not be etched excessively.

The mold layer 210 may be removed by a wet etching process using an etching solution or a dry etching process using an etching gas. The etching solution or the etching gas may have a lower etching rate with respect to the lower electrode 220 and a higher etching rate with respect to the mold layer 210.

For example, the mold layer 210 may be removed by the wet etching process using an LAL solution including deionized water, ammonium fluoride and/or hydrogen fluoride. In addition, the mold layer 210 may be removed by the dry etching process using the etching gas including hydrogen fluoride, isopropyl alcohol (IPA) and/or water vapor.

A cleaning process may be performed on the substrate 100. The cleaning process may remove any residue from the etching solution and/or particles that remaining on the sacrificial photoresist pattern 230 and the lower electrode 220. For example, the cleaning process may be carried out using isopropyl alcohol or deionized water.

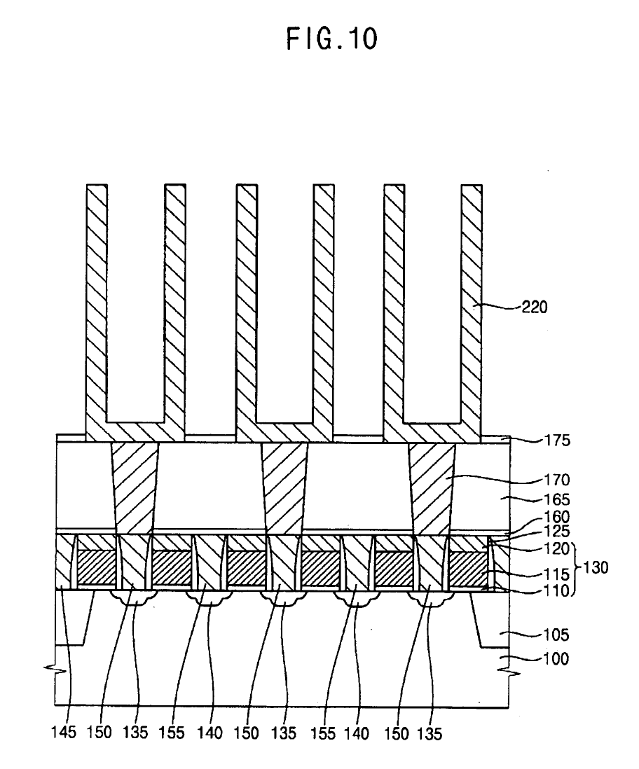

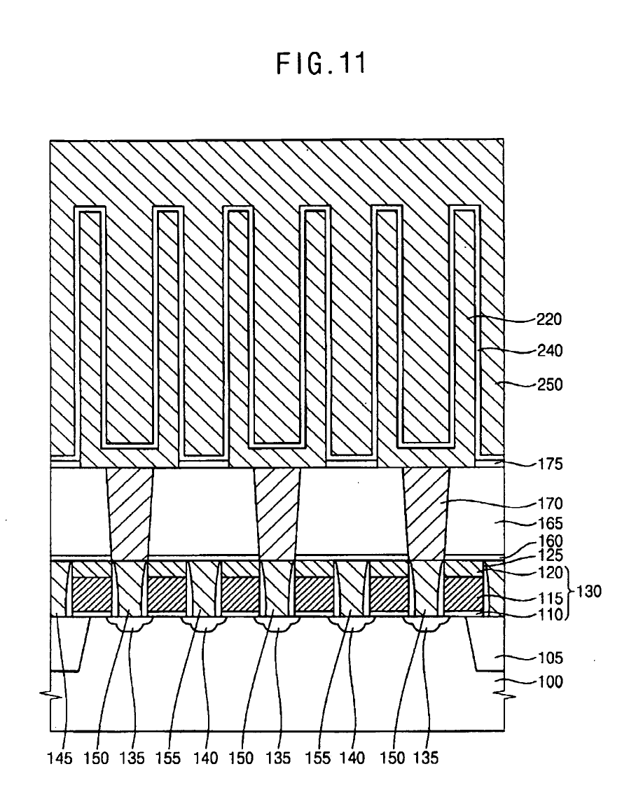

FIG. 10 is a cross sectional view illustrating an example process of removing the sacrificial photoresist pattern 230.

Referring to FIG. 10, the sacrificial photoresist pattern 230 may be removed from the lower electrode 220 such that residual photoresist from the sacrificial photoresist pattern 230 does not remain in the lower electrode 220. Thus, the lower electrode 220 having a cylindrical shape may be formed.

In an example embodiment of the present invention, the sacrificial photoresist pattern 230 may be removed from the lower electrode 220 using a plasma including directional active ions and radicals. Then, a rinsing process may be performed to remove the residual photoresist, from the sacrificial photoresist pattern 230, remaining on the lower electrode 220.

In another example embodiment of the present invention, the sacrificial photoresist pattern 230 may be removed from the lower electrode 220 using a plasma including directional active ions only. Then, a rinsing process may be performed to remove the residual photoresist, from the sacrificial photoresist pattern 230, remaining on the lower electrode 220.

In the process for removing the sacrificial photoresist pattern 230, the plasma including the directional active ions and the radicals may be generated over the substrate I 00 including the sacrificial photoresist pattern 230 thereon. The plasma may be generated when an RF power of about 1,000 W may be applied to a processing gas provided over the substrate 100. Simultaneously, a bias voltage of about 100V to about 300V may be applied to the substrate 100. Thus, the directional active ions may be generated. The directional active ions may be induced toward the substrate 100. In an example embodiment of the present invention, the plasma may include about 10 mole percent to about 90 mole percent of the directional active ions. In another example embodiment of the present invention, the plasma may include about 30 mole percent to about 70 mole percent of the directional active ions. The sacrificial photoresist pattern 230 that remains on the lower electrode 225 may be removed using the directional active ions as etching factors.

In an example embodiment of the present invention, the sacrificial photoresist pattern 230 may be removed at a temperature of about 10° C. to about 50° C. under a pressure of about 10 mTorr to about 800 mTorr. In another example embodiment of the present invention, the sacrificial photoresist pattern 230 may be removed at a temperature of about 10° C. to about 40° C. under a pressure of about 10 mTorr to about 500 mTorr.

The sacrificial photoresist pattern 230 may be removed by a reaction between polymers in the sacrificial photoresist pattern 230 and the directional active ions. The sacrificial photoresist pattern 230 may be removed at a temperature of less than about 250° C. and under a pressure of below about 1 Torr. Thus, when the sacrificial photoresist pattern 230 is removed from the lower electrode 220 by the directional active ions, undesirable occurrences (e.g., deterioration of the lower electrode 220 or adhesion characteristics between a metal layer and an insulation layer) may decrease.

A rinsing process may be performed on the substrate 100. The rinsing process may remove residual photoresist, from the sacrificial photoresist pattern 230, remaining on the lower electrode 225.

The sacrificial photoresist pattern 230 may be substantially removed without damage to the substrate 100 or deterioration of structures formed on the substrate 100, providing a more reliable semiconductor device. The sacrificial photoresist pattern 230 may be removed without increasing the removal process time. Thus, a manufacturing process of a semiconductor device may have increased throughput.

FIG. 11 is a cross-sectional view illustrating example processes forming a dielectric layer 240 and an upper electrode 250.

Referring to FIG. 11, a dielectric layer 240 may be formed on the lower electrode 220 by an ALD process or a CVD process. The dielectric layer 240 may be formed using a metal oxide. When the dielectric layer 240 is formed by the ALD process, the dielectric layer 240 may be formed using aluminum oxide or hafnium oxide.

An upper electrode 250 may be formed on the dielectric layer 240. The upper electrode 250 may be formed using doped polysilicon, a metal or a metal nitride. In addition, the upper electrode 250 may be formed by a CVD process. Thus, a capacitor including the lower electrode 220, the dielectric layer 240 and/or the upper electrode 250 may be formed over the substrate I 00.

Example Evaluation of a Removing Ability of a Photoresist Removal Method

An effect of a method of removing a photoresist in accordance with an example embodiment of the present invention was evaluated.

In order to evaluate a removing ability of a photoresist, a pattern having openings was formed on a substrate. An aspect ratio of the opening was about 1:15. A photoresist pattern having a thickness of about 20,000 Å was formed on the substrate to fill the opening. The photoresist pattern was formed using a novolac-based photoresist manufactured by Clariant Ltd., Japan.

The substrate was located on a stage in an inductive-coupled plasma (ICP) chamber. An oxygen gas having a flow rate of about 3,000 sccm, a nitrogen gas having a flow rate of about 250 sccm and an argon gas having a flow rate of about 400 seem are provided into the chamber. An RF power of about 2,000 W was applied to a plasma generator of the chamber. A bias voltage of about 150V was applied to the stage. Thus, a plasma including active ions and radicals was generated from the oxygen gas, the nitrogen gas and the argon gas. The active ions were to be directional by the bias voltage. The photoresist pattern was etched using the active ions as main etching factors for about six minutes. Then, the substrate was rinsed using deionized water.

A removing rate of the photoresist pattern was measured. A removed thickness of the photoresist pattern was about 15,000 Å. In a conventional ashing process, a processing time for removing a photoresist pattern having a thickness of about 15,000 Å is about 40 minutes. Thus, in accordance with example embodiments of the present invention, a photoresist pattern may be removed about six times faster than in the conventional ashing process. Therefore, a method of removing a photoresist using the active ions may increase a throughput in manufacturing of a semiconductor device.

According to example embodiments of the present invention, a photoresist is removed using directional active ions. The photoresist may be removed such that the photoresist does not remain in an opening having a higher aspect ratio (e.g., the opening for forming a lower electrode of a capacitor). Thus, increase of an electrical resistance may be retarded. In addition, the photoresist may be effectively removed without increasing of processing time or temperature. The likelihood of damaging a substrate or deteriorations of structures positioned on the substrate may decrease. Therefore, a manufacturing process of a semiconductor device may have increased throughput.

The foregoing is illustrative of the example embodiments of the present invention and is not to be construed as limiting thereof. Although example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of removing a photoresist comprising:
generating a plasma including active ions and radicals;
modifying the active ions into directional active ions; and
removing the photoresist using the directional active ions as main etching factors and the radicals as subsidiary etching factors.

2. The method of claim 1, wherein the plasma comprises about 10 mole percent to about 90 mole percent of the active ions.

3. The method of claim 1, wherein changing the active ions into the directional active ions is performed by applying a bias voltage to the active ions.

4. The method of claim 3, wherein the bias voltage is applied in a range of about 100V to about 300V.

5. The method of claim 1, wherein removing the photoresist is performed at a temperature of about 10° C. to about 50° C.

6. The method of claim 1, wherein removing the photoresist is performed under a pressure of about 10 mTorr to about 800 mTorr.

7. The method of claim 1, further comprising removing residue remaining on the substrate, after removing the photoresist.

8. The method of claim 1, further comprising filling an opening of a desired structure with the photoresist, prior to generating the plasma.

9. The method of claim 8, wherein an aspect ratio of the opening is in a range of about 1:9 to about 1:40.

10. A method of manufacturing a semiconductor device comprising:
forming a mold layer including a plurality of openings on a substrate;
forming a conductive layer on a sidewall and a bottom face of each opening, and the mold layer;
forming a photoresist film on the conductive layer to fill the opening;
partially removing the photoresist film and the conductive layer to form a photoresist pattern;
generating a plasma including active ions and radicals;
modifying the active ions into directional active ions; and
removing the photoresist pattern using the directional active ions as main etching factors and the radicals as subsidiary etching factors.

11. The method of claim 10, wherein the plasma comprises about 10 mole percent to about 90 mole percent of the active ions.

12. The method of claim 10, wherein changing the active ions into the directional active ions is performed by applying a bias voltage to the active ions.

13. The method of claim 12, wherein the bias voltage is applied in a range of about 100V to about 300V.

14. The method of claim 10, wherein removing the photoresist pattern is performed at a temperature of about 10° C. to about 50° C.

15. The method of claim 10, wherein removing the photoresist pattern is performed under a pressure of about 10 mTorr to about 800 mTorr.

16. The method of claim 10, further comprising removing residue remaining on the substrate, after removing the photoresist pattern.

17. The method of claim 10, wherein an aspect ratio of the opening is in a range of about 1:9 to about 1:40.
